(19) United States
(12) Patent Application Publication
(10) Pub. No.: US 2019/0363131 A1
(43) Pub. Date: Nov. 28, 2019

(54) MEMORY ARCHITECTURE HAVING DIFFERENT TYPE OF MEMORY DEVICES AND LOGIC CIRCUIT DISPOSED OVER A SEMICONDUCTOR SUBSTRATE

(71) Applicant: Gyrfalcon Technology Inc., Milpitas, CA (US)

(72) Inventors: Chyu-Jiuh Torng, Dublin, CA (US); Daniel H. Liu, San Jose, CA (US)

(73) Assignee: Gyrfalcon Technology Inc., Milpitas, CA (US)

(21) Appl. No.: 15/989,515

(22) Filed: May 25, 2018

(51) Int. Cl. H01L 27/24; G11C 5/02; H01L 45/00; G06N 3/08

(52) U.S. Cl. CPC H01L 27/24; G11C 5/02; G06N 3/08; H01L 45/145; H01L 45/08; H01L 45/1253

(57) ABSTRACT

This disclosure relates to embedding memories into with logic circuits for improving memory access speed and reducing power consumption. In particular, memories of distinct types embedded with logic circuits on a same semiconductor substrate are disclosed. These memories may include static random access memory, magnetoresistive random access memory, and various types of resistive random access memory. These different types of memories may be combined to form an embedded memory subsystem that provide distinct memory persistency, programmability, and access characteristics tailored for storing different type of data in, e.g., application involving convolutional neural networks.

### TECHNICAL FIELD

This disclosure generally relates to logic circuits embedded with memories on a same semiconductor substrate and particularly relates to embedding memories of distinct types with logic circuits for artificial intelligence applications based on, e.g., convolutional neural networks.

### BACKGROUND

Memory cells based on different technologies and operating principles may offer distinct characteristics in programmability, read/write speed, endurance, power consumption, cell density, and data persistency. Some complex applications, including but not limited to artificial intelligence applications based on neural networks, may be memory intensive and may process and use various types of data in disparate manners. For these applications, it may be preferably to use different types of memories corresponding to the different types of data. For example, a processing unit containing logic circuits may be configured to communicate with separate memory subsystems via data buses for data access. Each memory subsystem may include a dedicated memory controller and provide memory cells of a particular set of characteristics based on a specific memory technology.

### SUMMARY

This disclosure is directed to an integrated processor including logic circuits and embedded memory subsystem suitable for data intensive applications involving, e.g., convolutional neural network models and computations.

In one implementation, an integrated processor is disclosed. The integrated processor includes a contiguous semiconductor substrate, a logic circuit having a plurality of transistors disposed on at least a portion of the substrate, a first type of memory cells disposed over the substrate, wherein the first type of memory cells are non-volatile, a second type of memory cells disposed over the substrate, wherein the second type of memory cells are distinct from the first type of memory cells in operating principle, and one or more bit lines formed on the first type of memory cells and the second type of memory cells wherein the one or more bit lines interconnect with the logic circuit.

In the implementation of the integrated processor above, the second type of memory cells may be reprogrammable and at least one of the first type of memory cells may be configured in a one time programmable mode.

In the implementations of the integrated processor above, the second type of memory cells may include non-volatile magnetoresistive random access memory cells.

In the implementations of the integrated processor above, the first type of memory cells may include non-volatile resistive random access memory cells.

In the implementations of the integrated processor above, the non-volatile resistive random access memory cells may include oxygen vacancy random access memory cells or conductive bridge random access memory cells configured in a one time programmable mode.

In the implementations of the integrated processor above, the non-volatile resistive random access memory cells configured in one time programmable mode may be programmed at wafer level, chip level, or printed circuit board level.

In the implementations of the integrated processor above, the second type of memory cells may include static random access memory cells and the first type of memory cells may include non-volatile resistive random access memory cells. The non-volatile resistive random access memory cells may further include oxygen vacancy random access memory cells or conductive bridge random access memory cells configured in a one time programmable mode.

In the implementations of the integrated processor above, the logic circuit may be configured to read data from the first type of memory cells and the second type of memory cells via the one or more bit lines to perform one or more convolutional neural network computations.

In the implementations of the integrated processor above, the second type of memory cells may be configured to store frequently updated input data to be processed by the logic circuit in convolutional neural network computations and the first type of memory cells may be configured to store model parameters for the one or more convolutional neural network computations.

In the implementations of the integrated processor above, the first type of memory cells and the second type of memory cells may be disposed over the logic circuit.

In the implementations of the integrated processor above, the first type of memory cells and the second type of memory cells may be interlaced and non-overlapping in a plane parallel to the substrate.

In the implementations of the integrated processor above, the first type of memory cells and the second type of memory cells may be stacked on one another and may be disposed over the logic circuit.

The implementations of the integrated processor above may further include a third type of memory cells. The third type of memory cells may be non-volatile and may be distinct from the first type of memory cells and second type of memory cells in operating principle. The one or more bit lines may be formed over the first type of memory cells, the second type of memory cells, and the third type of memory cells.

In the implementations of the integrated processor above, the first type of memory cells may include non-volatile and reprogrammable resistive random access memory cells, the second type of memory cells may include non-volatile magnetoresistive random access memory cells, and the third type of memory cells may include non-volatile resistive random access memory cells configured in a one time programmable mode.

In the implementations of the integrated processor above, the logic circuit may be configured to read data from the first type of memory cells, the second type of memory cells, and the third type of memory cells via the one or more bit lines to perform one or more convolutional neural network computations. The first type of memory cells may be configured to store reprogrammable model parameters for the one or more convolutional neural network computations. The second type of memory cells may be configured to store frequently updatable input data for the one or more convolutional neural network computations. The third type of memory cells may be configured to store permanent model parameters for the one or more convolutional neural network computations.

In the implementations of the integrated processor above, the non-volatile resistive random access memory cells configured in the one time programmable mode may include oxygen vacancy random access memory cells or conductive bridge random access memory cells.

In the implementations of the integrated processor above, the first type of memory cells may include non-volatile and reprogrammable resistive random access memory cells. The second type of memory cells may include static random access memory cells. The third type of memory cells may include non-volatile resistive random access memory cells configured in a one time programmable mode.

Further objects, features, and advantages of this invention will become readily apparent to persons skilled in the art after a review of the following description, with reference to the drawings and claims that are appended to and form a part of this specification.

### BRIEF DESCRIPTION OF THE DRAWINGS

FIG. 1 illustrates a functional schematic of semiconductor processing unit containing logic circuits with a memory subsystem embedded on a same semiconductor substrate.

FIGS. 2A-2E illustrate cross-sectional schematic view of various implementations of a semiconductor processing unit containing logic circuits with a memory subsystem embedded on a same semiconductor substrate.

FIG. 3 illustrates a basic structure of a resistive random access memory cell.

FIG. 4 illustrates a cross-sectional view of resistive random access memory cells embedded with logic circuits on a same semiconductor substrate.

FIG. 5 illustrates a cross-sectional view of resistive random access memory cells and magnetoresistive random access memory cells embedded with logic circuits on a same semiconductor substrate.

### DETAILED DESCRIPTION

Random Access Memories (RAMs) and Central Processing Units (CPUs) are essential components of a computer system. For example, a memory subsystem of a computer may hold executable instructions and data. A CPU may be in communication with the memory subsystem and may be configured to execute the instructions and to process the data. The memory subsystem and the CPU may be manufactured independently on separate semiconductor substrates and embodied as separate semiconductor chips in communication with one another via memory busses. These inter-chip memory busses may impose a limitation on the communication speed of instructions and data between the memory subsystem and the CPU. In addition, such inter-chip communication of instructions and data may cause elevated power consumption because inter-chip electric signals that carry the instructions and data must be driven with sufficient voltage and current levels via I/O circuits in order to travel long paths between the memory subsystem and the CPU.

Embedding the memory subsystem with the CPU in the same semiconductor substrate may provide improvement in memory access speed and reduction in power consumption. Embedded memory may be alternatively referred to as on-chip memory. While the memory subsystem is introduced above in the context of processing system containing a CPU, it may be embedded with and configured to facilitate functioning of any other logic circuits. As such, the term “logic circuits” are broadly used herein to refer to any circuit for processing instructions and/or data.

An embedded memory subsystem is particularly advantageous for applications where a large amount of data need to be accessed and processed in real-time. These applications may include but are not limited to image processing, speech processing, natural language processing applications, and other data analytics applications. These applications, for example, may involve computation, training, and deployment of complex analytical and predictive models based on various machine learning techniques. In particular, a predictive model based on convolutional neural network (CNN) may require many millions of model parameters. Training of a CNN model and deployment of a trained CNN model may both involve processing a large amount of input data (e.g., a large collection of high resolution images) through a multilayer convolutional neural network having millions of various convolutional features, weight, and bias parameters.

Training and deployment of these predictive models are thus memory intensive. For some applications, training of predictive models may be performed offline in backend servers, and thus processing speed, power consumption may not be of a particular concern. Deployment and use of these trained models in the field, however, may be time-critical. While these models may be deployed and run in backend servers and users of these models may communicate with the backend servers for inputs and outputs, in some situations, it may be desirable to run these models in-situ and on user devices (e.g., mobile user devices powered by rechargeable batteries). In these scenarios, the deployment and use of the predictive models may be both time-critical and power sensitive. In some other applications, the predictive models may need to be improved upon and updated in real-time by implementing a feedback to training algorithms while the predictive models is being used. In such scenarios, continuous training of the predictive model may be needed and thus the training of the model in addition to the deployment and use of the model may be time-critical.

The time-critical and/or power sensitive training and/or deployment of these predictive models may require fast and repeated access of the millions of model parameters and other data (such as input data, e.g., images and speech data) in the memory subsystem. As such, it may be advantageous to embed the memory subsystem with the processing logic circuits in these applications.

The data and parameters for applications involving a predictive mode based on, e.g., CNN, may be accessed in various distinct manners and thus may be preferably stored in memory cells of various types having distinct physical characteristics. For example, memory cells for holding input data such as images and speech data may need to be refreshed and updated frequently during the use of the predictive model and thus may be implemented using durable memories cells that can withstand a large number of read/write cycles. For the same reason, these input data may not need to be persistently stored and thus volatile types of memory cells may be adequate. On the other hand, model parameters for some applications may be relatively static and may only need to be updated sparsely (when, e.g., a new version of the model is available). As such, storage of these model parameters may not require highly durable memory cells with respect to the number of read/write cycles. These memory cells for holding model parameters, however, may be preferably non-volatile such that the model parameters can be stored persistently in the memory cells unless and until they are deliberately erased and rewritten when, e.g., the predictive model is updated to a new version. In yet some other applications, the model parameters may need to be permanently stored in memory cells and kept unalterable and untamperable for security considerations. For these special types of model parameters, memory cells that are non-volatile and are one time programmable (OTP) may be preferable.

In one implementation, memory cells possessing some (even though not all) of these different characteristics above may be achieved using a same memory technology to provide memory cell arrays with varying physical parameters, such as cell size and cell spacing. An example that implements arrays of memory cells of different characteristics using spin transfer torque (STT) magnetic random access memory (MRAM) technology has been described in U.S. patent application Ser. No. 15/642,100, entitled “Embedded Spin Transfer Torque Memory for Cellular Neural Network Based Processing Unit”, filed on Jul. 5, 2017 by the same Applicant of this current patent application, which is hereby incorporated by reference in its entirety.

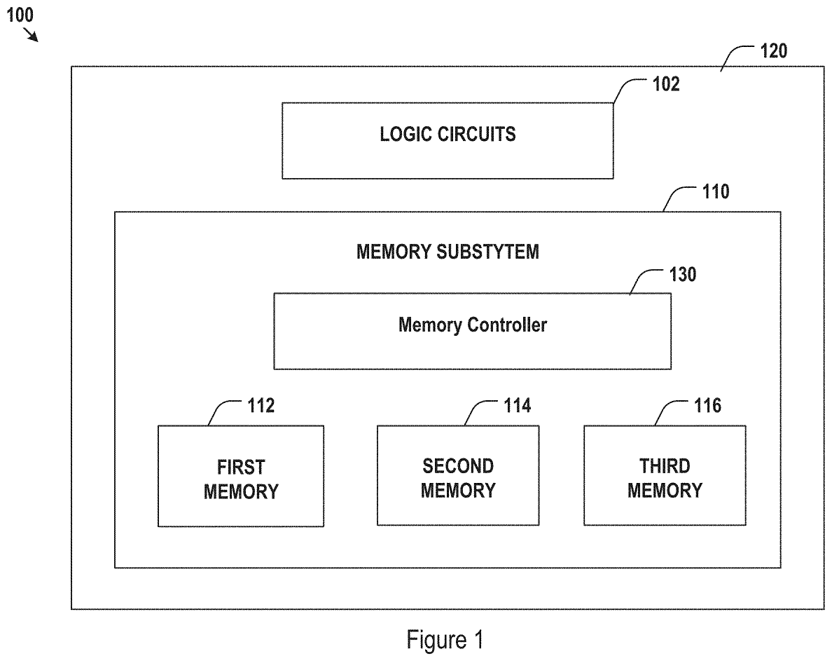

In another implementation, multiple distinct memory technologies may be used to achieve some or all of the memory cells of different characteristics above. For example, these memory cells based on different memory technologies and distinct operating principles may be integrally formed and embedded with logic circuits on a same semiconductor substrate, as illustrated in FIG. 1. Operating principles may relate to manners in which information is stored. For example, information may be stored as electric charge in a capacitor, as reprogrammable or one time programmable electric resistive or e-fuse states, as magneto resistive states, as bistable states in flip-flops based on bistability, and the like. In particular, FIG. 1 shows a schematic illustration of a single chip implementation 100 of logic circuits 102 and embedded memory subsystem 110 on a common semiconductor substrate 120. While logic circuits 102 are herein exemplarily described as being configured to implement training or deployment of a convolutional neural network for artificial intelligence applications, it may be alternatively configured to implement other types of neural networks, e.g., feedforward encoders, spiking neural networks, time delay neural networks, neuro-fuzzy networks, and recurrent neural networks, and may further be configured to implement any other general types of logic circuits for processing data.

The memory subsystem 110 of FIG. 1 may include a memory controller 130, a first memory 112, a second memory 114, and a third memory 116. The memory controller 130 may be configured to facilitate memory access by the logic circuits 102 by, e.g., performing address allocation and translation. In some implementations, memory cells of the memory subsystem 110 may be directly coupled to various portions of the logic circuits. As such, access to those memory cell may not need any involvement of the separate memory controller 130. In some implementations, the memory controller may be entirely removed. The first, second, and third memories 112, 114, and 116 may be delineated to designate memories of various functionality. In the context of application involving CNN, for example, the first memory may include memory cells that are preferably used for storing updatable/rewritable training parameters of a CNN model. The second memory 114 may include memory cells that are preferably used for storing input data that are processed by the CNN model. The input data may be, e.g., one or more digital images, one or more speech segments, one or more digital representations of natural language excerpts, and other input data. The CNN model implemented by the logic circuits 102 may be used, for example, to process the input data through the convolutional neural network to produce an output of a deterministic or probabilistic label for the input data that represents, e.g., a classification, a segmentation, or any other predictive properties for the input data. The third memory 116 may include memory cells that are preferably used for storing OTP parameters of the CNN model.

In some implementations, the first, second, and third memories 112, 114, and 116 are merely preferably rather than exclusively designated for storing data and parameters of various distinct characteristics as described above. The memory controller 130 may be responsible for maintaining an allocation table for associating different types of memories cells with different type of data or parameters as described above. The allocation table may be reconfigurable. For example, different types of memories cells may be cross allocated for various data and parameter use at different times when needed.

In some implementations, not all of the first, second, and third memories 112, 114, and 116 are included in the memory subsystem 110. For example, only the first and second memories 112 and 114 may be include with the first memories 112 used for storing model parameters and the second memories 114 used for storing input data. The first memories 112, for example, may be configured to be reprogrammable or may be configured to operate in the OTP mode.

In some implementations, the physical parameters of the memory cells may be varied for within one of the first, second, and third types of memories 112, 114, and 116 to further adjust characteristics of these memory cells. These physical parameters may include but are not limited to cell size and cell spacing, similar to the implementations described in U.S. patent application Ser. No. 15/642,100 by the same Applicant for the current patent application.

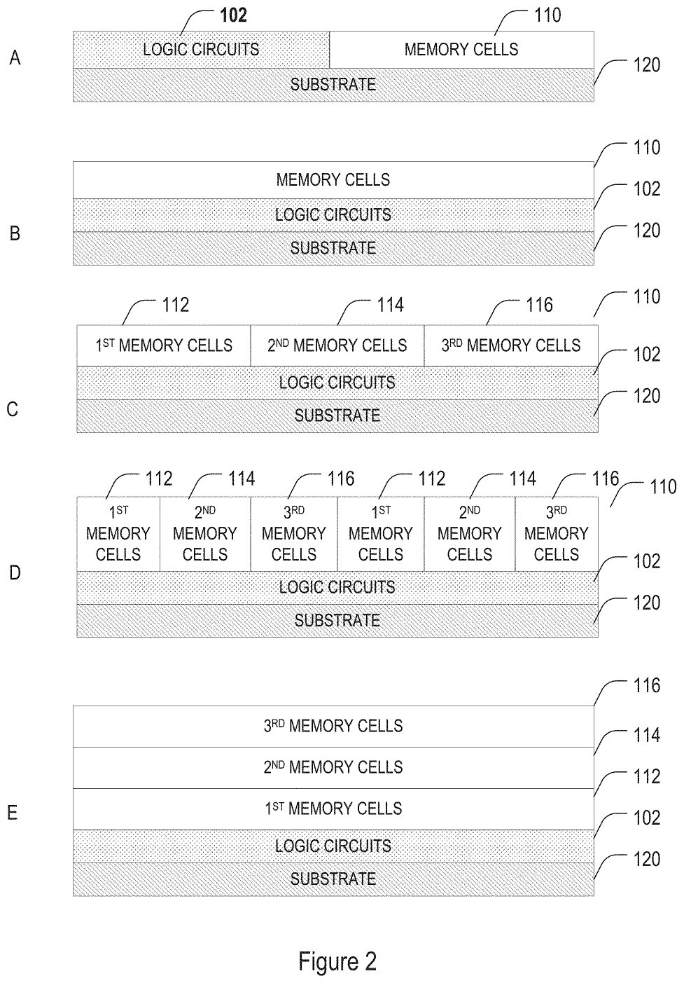

FIGS. 2A-2E further illustrates cross-sectional views of a semiconductor chip for various exemplary implementations of embedding the first, second, and third memories 112, 114, and 116 with the logic circuits 102. The semiconductor chip may be fabricated on the semiconductor substrate 120. In one implementation as shown in FIG. 2A, the logic circuits 102 and the memory cells of the memory subsystem 110 may be fabricated on separate portions of the semiconductor substrate 120. The interconnection between the logic circuits 102 and the memory cells 110 may be provided by metal lines that are disposed either on top of the logic circuits and memory cell structures or as interlayer metal lines.

Alternatively, as shown in FIG. 2B, the memory cells 110 and the logic circuits 102 may be fabricated as separate layered structures on the semiconductor substrate 120. For example, memory cells 110 may be fabricated on top of the logic circuits 102. Interconnection between the memory cells and elements of the logic circuits 102 may be provided directly using various metal vias or using metal vias in combination with one or more interlayer metal line. The first, second, and third memory cells 112, 114, and 116 may further be disposed in various relative spatial configurations as illustrated by the examples shown in FIGS. 2C, 2D, and 2E. For example, the first, second, and third memory cells 112, 114, and 116 (110, collectively) may be disposed in the same memory layer as shown by FIGS. 2C and 2D. In particular, the different type of memory cells may be disposed over the logic circuits 102 and distributed in the plane of the semiconductor substrate 120 in different areas (as shown FIG. 2C), or distributed as interlaced strips, grids, or other special configurations (as shown by FIG. 2D). In the latter configuration of FIG. 2D, for example, a same type of memory cells (the first memory cells 112, the second memory cells 114, or the third memory cells 116) may be distrusted over the entire logic circuits 102, facilitating local access of these memory cells by different portions of the logic circuits 102. For another example, the first, second, and third memory cells 112, 114, and 116 may be implemented as separate stacked memory layers on top of one another and over the logic circuits layer 120, as shown by the cross-sectional view in FIG. 2E. For this implementation, interconnection between the various types of memory cells and elements of the logic circuits 102, again, may be provided directly using metal vias or using metal vias in combination with one or more metal line layers.

In some implementations, buffering layers, stress releasing layers, adhesion layers, and/or other layers of materials may be disposed between the memory structures in FIG. 2E, and between the memory structures and logic circuits in FIGS. 2B, 2C, and 2D. For example, as described in U.S. patent application Ser. No. 15/642,100 by Applicant of this current application and referenced above, an adhesion and topography planarization (ATP) layer may be disposed between the logic circuits layers and MTJ layers of STT MRAM memory cells for providing a smoother surface for deposition of MTJ materials. Further, memory cells in each of the first, second and third memories 112, 114, and 116 may be implemented with same or different pitches and cell sizes. In some implementations, cell pitches and sizes within each array of the first second and third memories 112, 114, and 116 may be the same or different.

The first, second, and third memories 112, 114, and 116 may each be implemented using one of multiple memory technologies. These memory technologies may include but are not limited to static random access memory (SRAM), magnetoresistive random access memory (MRAM), eFuse-based memory, and resistive random access memory (RRAM) technologies. Memory cells formed using each of these memory technologies may provide a distinct set of properties. Integrating these different types of memories to form an embedded memory subsystem may thus provide a combination of memory cells for storing the input data and model parameters of a CNN model having a range of distinct characteristics.

SRAM memory technology, for example, may be based on traditional CMOS compatible processing. SRAM may include bistable latching circuitry (such as flip-flops) for storing information and each SRAM cell may contain a number of transistors. SRAM generally provide embedded volatile memory having fast access, low power consumption and high reliability/endurance.

The MRAM memory technology, for another example, may provide a non-volatile embedded memory based on programmable magnetoresistance in a magnetic tunnel junction (MTJ) in each memory cell. MRAM cells used for neural network applications may, for example, be based on spin transfer torque (STT), as described in more detail in U.S. patent application Ser. No. 15/642,100, and may particularly offer fast access (read/write) speed and small cell size with low power consumption. The MTJ layer may include a magnetic tunnel layer sandwiched between a pined layer and a free layer. The free layer of the MTJ layer may comprise CoxFeyBz, FexBy, FexBy/CoxFeyBz, CoxFeyBz/CoxFeyBz, CoxFeyBz/M/CoxFeyBz, FexBy/M/FexBy or FexBy/CoxFeyBz/M/CoxFeyBz, wherein M is metal. The MTJ layer may be etched and filled with dielectric materials between MTJs. In some implementations, the STT MRAM memory may also include a bit layer formed on top of the MTJ layer, such as over the free layer of the MTJ layer. Additionally, the STT memory may include a passivation layer and a bond pad (now shown), as known in the IC industry.

For eFuse-based memory technology, fusable metal links/structure are formed (electrically blown) for information storage, suitable for, e.g., OTP memory cells. The eFuse technology may provide a robust, high-speed, and secure non-volatile option for embedded memory cells.

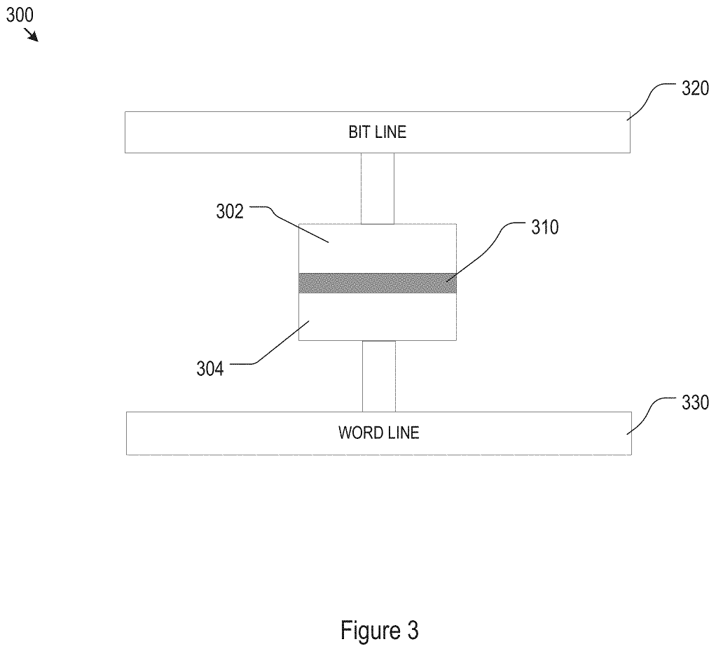

For another example, RRAM may be formed as non-volatile memory for storing information by changing and controlling electric resistance in memory cells. FIG. 3 illustrates a basic RRAM cell structure 300. The RRAM cell may include a layer of resistive switching material 310 sandwiched by electrodes 302 and 304 respectively connected to bit line 320 and word line 330. At the core of the RRAM cell, the resistive switching material 310 may be programmed (written) to exhibit various levels of electric resistance. Such resistance levels may be read/sensed to obtain stored information. In some implementations, an RRAM cell may be a binary cell exhibiting either a high resistance state representing logic zero or a low resistance state representing logic one. In some other implementations, an RRAM cell may be a multi-level cell for storing more than one bit of information. For example, a multi-level RRAM cell may exhibits four programmable resistive switching levels for storing two bits of information. In some implementations, an RRAM cells may be formed to represent five, six, seven, or larger number of bits of information.

Different types of RRAM may be implemented based on different resistive switching materials 310. For example, an RRAM may be formed based on metal-oxide as the resistive switching material. Such RRAM may be generally referred to as ReRAM. A metal-oxide used in ReRAM may include but is not limited to TaO, HfO2, and the like. A particular type of RRAM may be based on oxygen vacancies in transitional metal oxide and is herein referred to as OxRAM. In an OxRAM, a filament may be obtained by migration of oxygen vacancies for controlling the resistive state of the transition metal oxide. The metal oxide of an OxRAM may include but is not limited to binary metal oxide such as NiOx, TiOx, AIOx, and TaOx, and perovskite oxides such as SrTiOx and SrZrOx. OxRAM, for example, may be programmed via controlled soft breakdown of the metal oxide dielectric material to create a vacancy filament. Such dielectric breakdown may be controlled to be reversible and as a result. As such, the OxRAM cell may be reprogrammable. In some implementations, because reversing the vacancy filament may not be complete and as such, number of write cycles that may be formed for such OxRAM cells may be limited. In some other implementations, the OxRAM may be irreversibly programmed using bias voltages that are higher than the normal programming voltage, and may be used as one time programmable (OTP) memory.

Alternatively, the resistive switching material 310 of an RRAM of FIG. 3 may be based on another type of filament formation, herein referred to as conductive bridge RAM (CBRAM). Particularly for some implementations, layer 310 of FIG. 3 may comprise a thin film of solid electrolyte, such as GeS, ZrOx, TaOx, GeSe and the like, sandwiched between electrochemically active electrodes including but not limited to Ag and Cu, and electrochemically inert counter electrode including but not limited to W. The filament or conductive bridge formation in CBRAM may be based on metallic ion generation and deposition at the electrochemically active electrode. Similar to OxRAM, CBRAM may be programmed to low resistance state (with filament formation) and may further be reversed or reset by dissolving the filament with reverse bias. In some implementations, the CBRAM may be irreversibly programmed and may be used as one time programmable (OTP) memory.

In some implementations, a RRAM memory cell above may be formed with widths ranging from 20 to 500 nm and length ranging from 100 nm to 2 mm in the growth plane of the semiconductor substrate. For a MRAM cell, the MTJ may be formed with a width raging from 20 nm to 200 nm. In some other implementations, OxRAM or CBRAM type of RRAM may be formed with a width ranging from 20 nm to 150 nm. Particularly for RRAM configured to operate as OTP memory cells, smaller cell size (width) may provide lower programming voltages. For example, the OxRAM or the CBRAM cells may be formed with smaller width than the MRAM cells to reduce the breakdown voltage need to for the oxide barrier layer when programming the OxRAM or CBRAM memory cells. The read/write voltage of the OxRAM and CBRAM used as OTP memory may be set higher than normal read/write voltages. For example, the OTP programming voltage may be set to approximately 9 Volt or other values higher than normal programming voltages.

In some implementation of the memory subsystem 110 of FIG. 1, only the first memory 112 and the second memory 114 may be included. The first memory 112 may be formed as RRAM cells and the second memory 114 may be formed as SRAM or MRAM cells. The RRAM cells may operate in either normal mode or OTP mode. The first memory 112 may be used, for example, to store model parameters, and the second memories 114 may be used to store input data.

In some other implementations, the first, second, and third memories 112, 114, and 116 may be included in the memory subsystem 110. The first and third memories 112 and 116 may be formed as RRAM cells and the second memory 114 may be formed as SRAM or MRAM cells. The first and third memories 112 and 116 may be used, for example, to store model parameters, and the second memories 114 may be used to store input data. The first memory 112, for example, may be formed as RRAM cells operated under normal read/write mode for storing model parameters of the neural network that may be updatable. The third memory 116, for another example, may be formed as RRAM cells operated under OTP mode for storing model parameters of the neural networks that cannot be altered for, e.g., security reasons.

In some other implementations, the first, second, and third memories 112, 114, and 116 may be included in the memory subsystem 110. The first and second memories 114 may be formed as SRAM or MRAM cells, and the third memory 116 may be formed as an OTP type of RRAM cells. The first memory 112, e.g., may be used to store updatable model parameters for the neural networks. The second memory 114 may be used, e.g., to store input data. The third memory 116, e.g., may be used to store permanent model parameters for the neural networks that may not be changed due to, e.g., security reasons.

To the extent that OTP type of RRAM cells are used in the memory subsystem 110 of FIG. 1, they may be programmed at various stages during their fabrication or use. For example, they may be programmed at wafer level during the fabrication process of the logic circuits and memory subsystem 100 of FIG. 1. They may be alternatively programmed at chip level when each chip containing the logic circuits and embedded memories is being processed, tested, or packaged. They may also be alternatively programmed at a printed circuit board level after the chip is placed onto a circuit board.

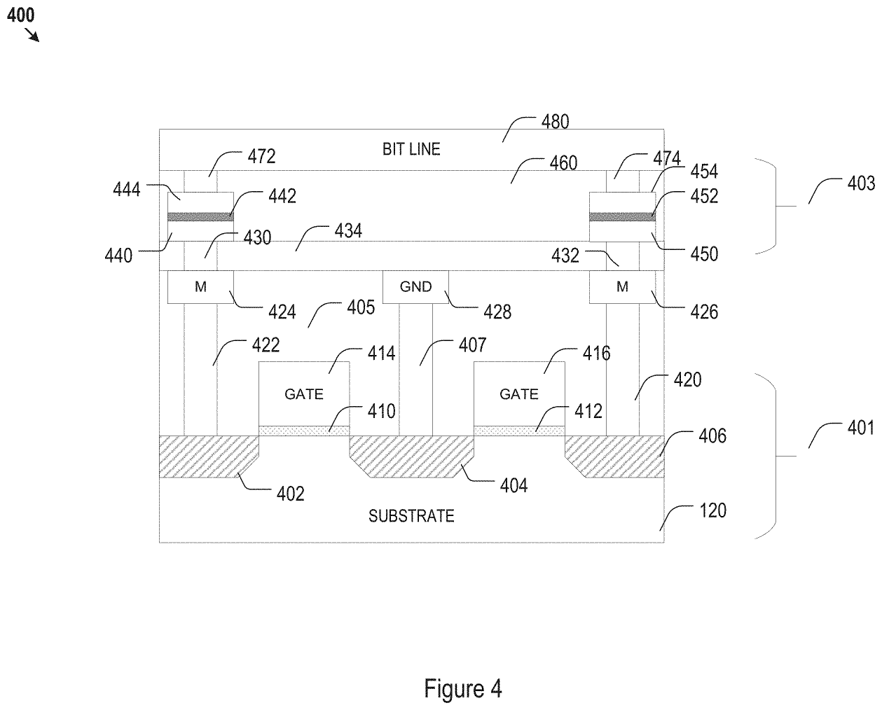

FIG. 4 further illustrates a cross-sectional view of RRAM memory cells embedded with logic circuits in an exemplary implementation. In this example, the logic circuits 401 may be fabricated on the semiconductor substrate 120 following normal CMOS fabrication processes. The RRAM memory cells 403 may be further fabricated over the logic circuits 401. The logic circuits, for example may include one or more logic gates comprising sources/drains 402, 404, and 406, gate insulator layer 410 and 412, and gates 414 and 416. The logic gates may be encapsulated by interlayer dielectrics 405 (silicon oxide, for example) with metal pads 424, 426, and 428 connected to sources/drains 402, 404, and 406 by vias 422, 407 and 420 through the interlayer dielectrics 405.

The RRAM memory cells 403 of FIG. 4 may be spaced from the logic circuit layers by a dielectric layer 434 and fabricated over the dielectric layer 434. For example, metal oxide layer 442 may be sandwiched between electrodes 444 and 440 to form one RRAM cell. Likewise, metal oxide layer 452 may be sandwiched between electrodes 454 and 450 to form another RRAM cell. The RRAM cells may be isolated laterally by dielectric layer 460. The memory cells 403 may be electrically connected to the metal pads 430, 424 and 426 for the logic circuits using vias 430 and 432 when needed. Bit lines 480 may be further disposed over the RRAM cells and are connectable to the memory cells using via 472 and 474 through the dielectric layer 460.

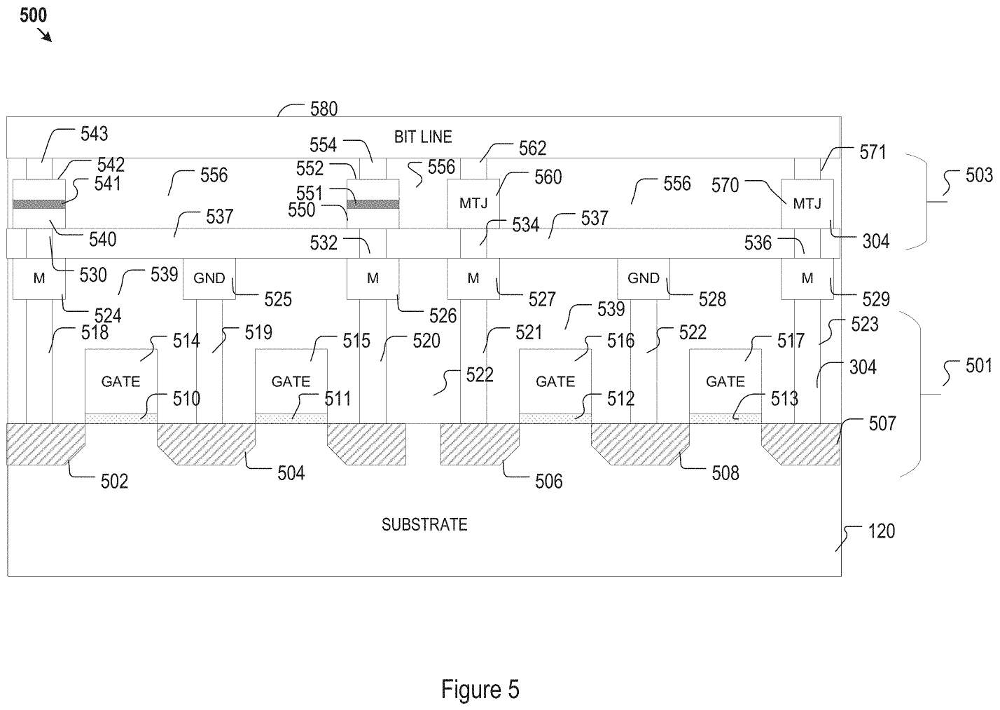

FIG. 5 further illustrates a cross-sectional view of RRAM and MRAM memory cells embedded with logic circuits in an exemplary implementation (such as implementations in FIGS. 2C and 2D). In this example, the logic circuits 501 may be fabricated on the semiconductor substrate 120 following normal CMOS fabrication processes. The RRAM memory cells and MRAM memory cells 503 may be further fabricated over the logic circuits 501. The logic circuits, for example may include one or more logic gates comprising sources/drains 502, 504, 506, 508, and 507, gate insulator layer 510, 511, 512, and 513, and gates 514, 515, 516, and 517. The logic gates may be capsulated by interlayer dielectrics 539 (silicon oxide, for example) with metal pads 524, 525, 526, 527, 528, and 529 connected to sources/drains 502, 504, 506, 508, and 507 by vias 518, 519, 520, 521, 522, and 523 through the interlayer dielectrics 539.

The RRAM and MRAM memory cells 403 may be spaced from the logic circuit layers by a dielectric layer 537 and fabricated over the dielectric layer 537. For example, metal oxide layer 541 may be sandwiched between electrodes 540 and 542 to form one RRAM cell. Likewise, metal oxide layer 551 may be sandwiched between electrodes 550 and 552 to form another RRAM cell. For another example, the MTJ structures 560 and 570 may be fabricated over the dielectric layer 537 to form MRAM cells. The RRAM cells and the MRAM cells may be isolated laterally by dielectric layer 556. The memory cells 503 may be electrically connected to the metal pads 524, 525, 526, 527, 528, and 529 for the logic circuits using vias 530, 532, 534, and 536 when needed. Bit lines 580 is further disposed over the RRAM and MRAM cells and are connectable to the memory cells using via 543, 554, 562, and 571 through the dielectric layer 556.

In the implementation of FIG. 5 above, the fabrication or the RRAM cells and the MRAM cells may be implemented independently using various masks such that RRAM layers are only deposited and processed in areas of the dielectric layer 537 designated for the RRAM, and MRAM layers are only deposited and processed in areas of the dielectric layer 537 designated for the MRAM cells. In some implementations, thickness of each individual material layer within each type of memory cells may be independently controlled/adjusted. As a result, the MRAM cell structure and the RRAM structure may be different in overall height above the logic circuits in FIG. 5. For example, the MTJ 560 and 570 structures and the metal oxide layers 541 and 551 may be at different height levels in FIG. 5. In some implementations, even though the RRAM and MRAM structures may be of different heights at various layers, the dielectric layer 556 may be formed and then planarized/flattened such that the bit line 580 and other metal layers may be formed over a flat and leveled surface of the dielectrics 556.

While the logic gates of the logic circuits 401 and 501 of FIGS. 4 and 5 are depicted as traditional COMS FET structures, other types of logic gate structures may be used. For example, the logic circuits 401 and 501 of FIGS. 4 and 5 may be based on FinFET structures for reducing short channel effects in a traditional CMOS FET structure with small channel width.

The description and accompanying drawings above provide specific example embodiments and implementations. Drawings containing circuit and system layouts, cross-sectional views, and other structural schematics, for example, are not necessarily drawn to scale unless specifically indicated. Subject matter may, however, be embodied in a variety of different forms and, therefore, covered or claimed subject matter is intended to be construed as not being limited to any example embodiments set forth herein. A reasonably broad scope for claimed or covered subject matter is intended. Among other things, for example, subject matter may be embodied as methods, devices, components, or systems. Accordingly, embodiments may, for example, take the form of hardware, software, firmware or any combination thereof.

Throughout the specification and claims, terms may have nuanced meanings suggested or implied in context beyond an explicitly stated meaning. Likewise, the phrase “in one embodiment/implementation” as used herein does not necessarily refer to the same embodiment and the phrase “in another embodiment/implementation” as used herein does not necessarily refer to a different embodiment. It is intended, for example, that claimed subject matter includes combinations of example embodiments in whole or in part.

In general, terminology may be understood at least in part from usage in context. For example, terms, such as “and”, “or”, or “and/or,” as used herein may include a variety of meanings that may depend at least in part on the context in which such terms are used. Typically, “or” if used to associate a list, such as A, B or C, is intended to mean A, B, and C, here used in the inclusive sense, as well as A, B or C, here used in the exclusive sense. In addition, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

Reference throughout this specification to features, advantages, or similar language does not imply that all of the features and advantages that may be realized with the present solution should be or are included in any single implementation thereof. Rather, language referring to the features and advantages is understood to mean that a specific feature, advantage, or characteristic described in connection with an embodiment is included in at least one embodiment of the present solution. Thus, discussions of the features and advantages, and similar language, throughout the specification may, but do not necessarily, refer to the same embodiment.

Furthermore, the described features, advantages and characteristics of the present solution may be combined in any suitable manner in one or more embodiments. One of ordinary skill in the relevant art will recognize, in light of the description herein, that the present solution can be practiced without one or more of the specific features or advantages of a particular embodiment. In other instances, additional features and advantages may be recognized in certain embodiments that may not be present in all embodiments of the present solution.

From the foregoing, it can be seen that this disclosure provides a semiconductor chip architecture including logic circuits embedded with various types of memories for improving memory access speed and reducing power consumption. In particular, memories of distinct types embedded with logic circuits on a same semiconductor substrate are disclosed. These memories may include static random access memory, magnetoresistive random access memory, and various types of resistive random access memory. These different types of memories may be combined to form an embedded memory subsystem that provide distinct memory persistency, programmability, and access characteristics tailored for storing different type of data in, e.g., application involving convolutional neural networks.

1. An integrated processor, comprising:
a contiguous semiconductor substrate;
a logic circuit having a plurality of transistors disposed over at least a portion of the substrate;
a first type of memory cells disposed over the substrate, wherein the first type of memory cells are non-volatile;
a second type of memory cells disposed over the substrate, wherein the second type of memory cells are distinct from the first type of memory cells in operating principle; and
one or more bit lines formed over the first type of memory cells and the second type of memory cells wherein the one or more bit lines interconnect with the logic circuit.

2. The integrated processor of claim 1, wherein the second type of memory cells are reprogrammable and at least one of the first type of memory cells is configured in a one time programmable mode.

3. The integrated processor of claim 1, wherein the second type of memory cells comprise non-volatile magnetoresistive random access memory cells.

4. The integrated processor of claim 3, wherein the first type of memory cells comprise non-volatile resistive random access memory cells.

5. The integrated processor of claim 4, wherein the non-volatile resistive random access memory cells comprises oxygen vacancy random access memory cells or conductive bridge random access memory cells configured in a one time programmable mode.

6. The integrated processor of claim 5, wherein the non-volatile resistive random access memory cells configured in one time programmable mode are programmed at wafer level, chip level, or printed circuit board level.

7. The integrated processor of claim 1, where the second type of memory cells comprise static random access memory cells and the first type of memory cells comprise non-volatile resistive random access memory cells.

8. The integrated processor of claim 7, wherein the non-volatile resistive random access memory cells comprises oxygen vacancy random access memory cells or conductive bridge random access memory cells configured in a one time programmable mode.

9. The integrated processor of claim 1, wherein the logic circuit is configured to read data from the first type of memory cells and the second type of memory cells via the one or more bit lines to perform one or more convolutional neural network computations.

10. The integrated processor of claim 9, wherein the second type of memory cells are configured to store frequently updated input data to be processed by the logic circuit in convolutional neural network computations and wherein the first type of memory cells are configured to store model parameters for the one or more convolutional neural network computations.

11. The integrated processor of claim 1, wherein the first type of memory cells and the second type of memory cells are disposed over the logic circuit.

12. The integrated processor of claim 11, wherein the first type of memory cells and the second type of memory cells are interlaced and non-overlapping in a plane parallel to the substrate.

13. The integrated processor of claim 1, wherein the first type of memory cells and the second type of memory cells are stacked over one another and are disposed over the logic circuit.

14. The integrated processor of claim 1, further comprising a third type of memory cells, wherein the third type of memory cells are non-volatile and are distinct from the first type of memory cells and second type of memory cells in operating principle, and wherein the one or more bit lines are formed over the first type of memory cells, the second type of memory cells, and the third type of memory cells.

15. The integrated processor of claim 14, wherein the first type of memory cells comprise non-volatile and reprogrammable resistive random access memory cells, the second type of memory cells comprise non-volatile magnetoresistive random access memory cells, and the third type of memory cells comprises non-volatile resistive random access memory cells configured in a one time programmable mode.

16. The integrated processor of claim 15, wherein:
the logic circuit is configured to read data from the first type of memory cells, the second type of memory cells, and the third type of memory cells via the one or more bit lines to perform one or more convolutional neural network computations;
the first type of memory cells are configured to store reprogrammable model parameters for the one or more convolutional neural network computations;
the second type of memory cells are configured to store frequently updatable input data for the one or more convolutional neural network computations; and
the third type of memory cells are configured to store permanent model parameters for the one or more convolutional neural network computations.

17. The integrated processor of claim 15, wherein the non-volatile resistive random access memory cells configured in the one time programmable mode comprise oxygen vacancy random access memory cells or conductive bridge random access memory cells.

18. The integrated processor of claim 14, wherein the first type of memory cells comprise non-volatile and reprogrammable resistive random access memory cells, the second type of memory cells comprise static random access memory cells, and the third type of memory cells comprises non-volatile resistive random access memory cells configured in a one time programmable mode.

19. The integrated processor of claim 18, wherein:
the logic circuit is configured to read data from the first type of memory cells, the second type of memory cells, and the second type of memory cells via the one or more bit lines to perform one or more convolutional neural network computations;
the first type of memory cells are configured to store reprogrammable model parameters for the one or more convolutional neural network computations;
the second type of memory cells are configured to store frequently updatable input data for the one or more convolutional neural network computations; and
the third type of memory cells are configured to store permanent model parameters for the one or more convolutional neural network computations.

20. The integrated processor of claim 18, wherein the non-volatile resistive random access memory cells configured in the one time programmable mode comprise oxygen vacancy random access memory cells or conductive bridge random access memory cells.
